(19) United States
(12) Patent Application Publication
(10) Pub. No.: US 2018/0004877 A1
(43) Pub. Date: Jan. 4, 2018

(54) Method and Apparatus for Collecting Signal Values in FPGA Based Emulation Machine

(71) Applicant: Synopsys, Inc., Mountain View, CA (US)

(72) Inventor: Mikhail Bershteyn, Mountain View, CA (US)

(21) Appl. No.: 15/596,637

(22) Filed: May 16, 2017

Related U.S. Application Data
(60) Provisional application No. 62/342,800, filed on May 27, 2016.

(51) Int. Cl. G06F 17/50; H03K 19/177

(52) U.S. Cl. CPC G06F 17/5027; H03K 19/17728; G06F 17/5054; G06F 17/5068

(57) ABSTRACT

Systems and methods for collecting signal values in FPGA based emulation machine. A single LUT is used to observe three observable points within a VLSI. A 6-input LUT is used to implement scan cells. Each scan cell implements a 4:1 multiplexer using the 6-input LUT. Each scan cell also uses three registers. The first and second register are used to sample and hold signals from the first two of the three observable points associated with that scan cell. The third register is used to capture the output of the 4:1 multiplexer.

### CROSS-REFERENCE TO RELATED APPLICATIONS—CLAIM OF PRIORITY

The present application claims priority to U.S. Provisional Application No. 62/342,800, filed on May 27, 2016, entitled “Method and Apparatus for Collecting Signal Values in FPGA Based Emulation Machine”, which is herein incorporated by reference in its entirety.

### TECHNICAL FIELD

### Background

An emulation machine is an apparatus used for verifying design correctness prior to fabrication, typically in the form of very large scale integrated circuits (VLSI). These machines are commonly built using field programmable gate array devices (FPGA), such as the FPGAs manufactured by XILINX Inc., Intel Corp., and others.

The logic design under verification is commonly partitioned (by software or manually) into fragments fitting into a single FPGA device, each interconnected by an FPGA interconnect available in the emulation machine. Once the fragments are programmed into all of the FPGA devices being used, the emulation machine is made to function in the same way as the future VLSI will function when it is later fabricated. In this way, the design of the VLSI can be assessed to determine whether it is accurate and will operate as expected.

In many cases, the initial version of the design will fail to exhibit the desired functionality when loaded into an emulation machine. It is typically useful to investigate the reasons for such failures so that necessary corrections can be made. This process may be repeated several times. This process of correction and verification of the design is commonly called debugging. Performing such debugging using an emulation machine is significantly faster and cheaper than the process of repeatedly fabricating and evaluating of actual VLSI.

To enable effective debugging, a way is preferably provided for the emulation machine to observe the values of design signals over time. Such design signals typically change in successive clock cycles. One way that is commonly implemented is to use an embedded programmable logic analyzer. The embedded logic analyzer can be instructed to observe particular signals during particular time intervals. The data path of the embedded logic analyzer is commonly implemented using a plurality of registers connected as “scan chains”. For example, U.S. Pat. No. 5,960,191 teaches one such scan chain using 2:1 multiplexers that can be programmed to either load signal values into a register from the observable point in a design, or to scan the previously loaded values out into an external storage.

FIG. 1 is a diagram showing a data path for a logic analyzer implemented as “scan chain” according to prior art. A scan chain provides a means by which a set of observation points within a user logic design can be observed in turn. Each of the plurality of observation points in user logic is connected to one input to a multiplexer 2005, 2007, 2009. The output of each multiplexer 2005, 2007, 2009 is connected to an input of an associated register 2004, 2006, 2008. A second input of the multiplexer 2007 is connected to the output of the previous register 2004 in the scanning order. Similarly, the second input of the multiplexer 2009 is coupled to the output of the register 2006. The last register 2008 in the chain produces an output 2010 that is connected through some appropriate means of communication to external storage where the resulting signal values are kept.

The inserted scan logic 2000 is added to the user logic. The combination of the scan logic and the user logic comprise the overall circuit 10 loaded into FPGA device. The apparatus operates as follows. At a chosen point in time, a value is applied to selection control inputs of all multiplexers 2005, 2007, 2009 such that the value at each multiplexer input that is connected to the user logic is propagated to the inserted logic output 2010. Upon a transition of a clock signal to each of the registers 2004, 2006, 2008, the value at the output of the multiplexers 2005, 2007, 2009 is captured in the registers 2004, 2006, 2008.

Following this “capture” cycle a sequence of scan cycles occurs. During the scan cycles, a “scan control” value is applied to selection control inputs of the multiplexers 2005, 2007, 2009 to apply the output of the multiplexer previous in scanning order to their output. Upon subsequent transitions of the clock, all values stored in registers 2004 during capture cycle will sequentially appear at the output 2010, thus allowing all of the captured values to be reviewed at the output.

During the sequence of scan cycles, the user logic can continue to operate as desired, assuming it is sufficient for the debugging operation to capture one out of each N subsequent states of the user logic. It is a common practice known to those skills in the art to reconstruct missing values using a simulation process performed by software.

Alternatively, during the sequence of scan cycles, user logic may be held stable. This allows the debugging process to capture every one of the user logic's subsequent states. However, this comes at the cost of reducing the operating speed of the user logic.

One disadvantage of the prior art solution is that each multiplexer 2005, 2007, 2009 requires one programmable lookup table (LUT). Thus, the required overhead is one LUT and one register for each observation point in user logic. This increases the size of the overall circuit 10 that needs to be programmed into each FPGA. Although registers are typically available in abundance in modern FPGA devices, the need for one 2:1 multiplexer for each observation point requires the use of one programmable lookup table (LUT) for each multiplexer. Each LUTs could hold a logic equivalent of 3 to 4 gates in a design under verification. Accordingly, this constitutes a significant cost overhead in the emulation machine, in addition to the overhead required to emulate the design itself.

Accordingly, there is presently a desire for a more efficient method and apparatus for capturing samples during emulation.

### SUMMARY

Various embodiments of a method and apparatus for collecting signal values in FPGA based emulation machine are disclosed. In some such embodiments, a single LUT is used to observe three observable points within a VLSI. In some embodiments, a 6-input LUT is used to implement a scan cell. Each scan cell implements a 4:1 multiplexer using the 6-input LUT. Three of the inputs to the 4:1 multiplexer are used to capture signals at observable points in the VLSI. The fourth input of the 4:1 multiplexer is used to receive information regarding a signal captured in a previous scan cell. Each scan cell also uses three registers. The first and second register are used to sample and hold signals from the first two of the three observable points associated with that scan cell. The third register is used to capture the output of the 4:1 multiplexer. Two selection control inputs to the 4:1 multiplexer determine the value to be presented at the multiplexer data output based on the values presented at a selected data input of the multiplexer. A clock signal is applied to each of the registers. The clock signal allows information from the observable points of the VSLI to be captured in the registers and can be synchronized with the selection control inputs to the multiplexer to allow the signal at each observable point to be directed to the output of the multiplexer in turn. By having the fourth input of the multiplexer coupled to the output of a scan cell that is present earlier in the scan chain, several such scan cells can be used together to allow as many point as desired to be observed.

### BRIEF DESCRIPTION OF THE DRAWINGS

The disclosed method and apparatus, in accordance with one or more various embodiments, is described with reference to the following figures. The drawings are provided for purposes of illustration only and merely depict examples of some embodiments of the disclosed method and apparatus. These drawings are provided to facilitate the reader's understanding of the disclosed method and apparatus. They should not be considered to limit the breadth, scope, or applicability of the claimed invention. It should be noted that for clarity and ease of illustration these drawings are not necessarily made to scale.

FIG. 1 is a diagram showing a logic analyzer data path implemented in a scan chain according to the prior art.

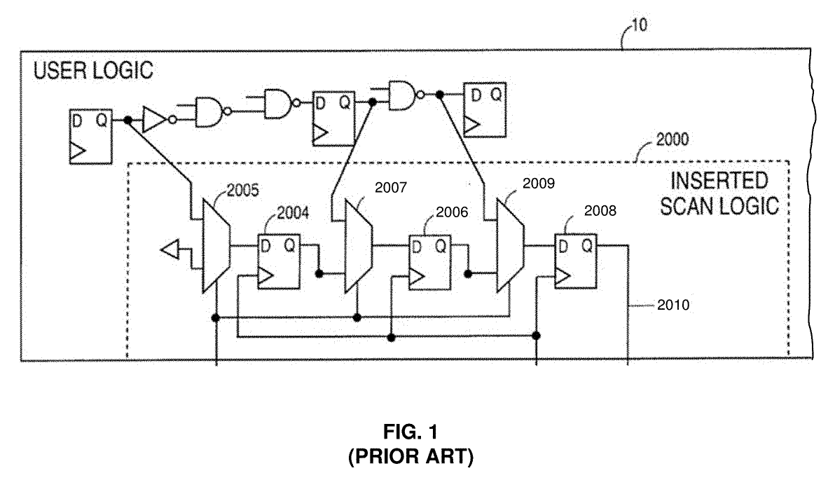

FIG. 2 is a diagram showing a logic analyzer data path according to the presently disclosed method and apparatus.

FIG. 3 is a timing diagram of the logic analyzer showing the state of the selection control inputs.

The figures are not intended to be exhaustive or to limit the claimed invention to the precise form disclosed. It should be understood that the disclosed method and apparatus can be practiced with modification and alteration, and that the invention should be limited only by the claims and the equivalents thereof.

### DETAILED DESCRIPTION

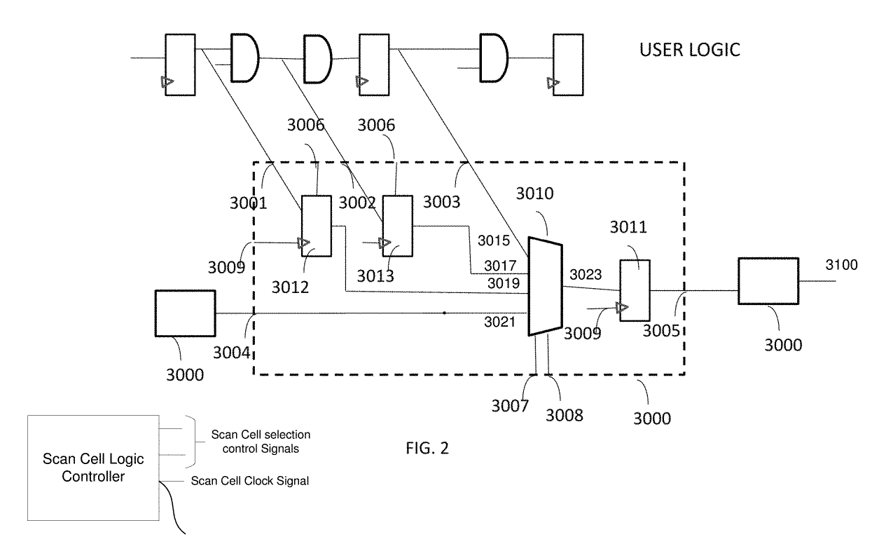

FIG. 2 is a diagram showing logic analyzer scan chain according to some embodiments of the disclosed method and apparatus. The depicted logic analyzer scan chain takes advantage of the fact that an LUT element, such as that used in most of the modern FPGA devices can be used to implement a 4:1 multiplexer 3010. One such FPGA device is manufactured by XILINX Inc. An LUTs having 6 inputs can implement an arbitrary Boolean function of 6 variables. In some cases, by a proper programming, it is possible to use the LUT to implement a 4:1 multiplexer 3010 with 2 selection control inputs 3007, 3008 and a multiplexer data output 3023. The values of the two selection control inputs 3007, 3008 are used to select one of the 4 multiplexer data inputs 3015, 3017, 3019, 3021. That is, the truth table of the LUT mask is such that the value of the signals applied to the two selection control inputs and the value of the input to which the selection control signals point, will determine value of the output. The selected value can be propagated to a data output 3023 of the multiplexer 3010.

Scan chain according to the presently disclosed method and apparatus consists of sequentially connected scan cells 3000. Each of the cells 3000 has 4 scan cell data inputs 3001, 3002, 3003, 3004. Three of these scan cell data inputs 3001, 3002, 3003 are connected to the observation points in user logic associated with the scan cell 3000. The fourth scan cell data input 3004 of the cell 3000 is connected to the output 3005 of scan cell 3000 previous in the scanning order. The output 3100 of the last scan cell 3000 in a chain is connected through appropriate means of communication, to external storage. Load enable control input 3006, selection control inputs 3007, 3008, and scan cell clock input 3009 are coupled to corresponding inputs on all other scan cells 3000. Each scan cell 3000 consists of a 4:1 multiplexer 3010, and three registers 3011, 3012, 3013. The multiplexer data inputs of the 4:1 multiplexer 3010 are connected respectively to the scan cell 3000 inputs 3003, 3004 and the outputs of registers 3012, 3013. The output 3023 of multiplexer 3010 is connected to the D-input of the register 3011. The D-inputs of the registers 3012, 3013 are connected respectively to scan cell inputs 3001, 3002.

Register clock inputs to the registers 3011, 3012, 3013 are connected to the scan cell clock input 3009 of scan cell 3000. It will be noted that, for ease of drawing, the signal applied to the scan cell clock input 3009 to each register 3011, 3012, 3013 are not shown explicitly as being connected to one another in FIG. 2. The clock enable inputs of registers 3012, 3013 are connected to a load enable control input 3006 of the scan cell 3000. In some embodiments, the clock enable inputs to the two registers 3012, 3013 are connected together, though not explicitly shown in FIG. 2 for ease of drawing. In some embodiments, the signal applied to the clock enable input of register 3011 is always set to the enable state. Therefore, the clock enable input to register 3011 is not shown in FIG. 2. Selection control inputs 3007, 3008 of scan cell 3000 are connected to the multiplexer 3010 selection control inputs.

It can be seen from the above description, that such a scan cell can be configured for any number of observation points equal to N−1, using a (N+log₂(N)) input LUT to form a N:1 multiplexer and N−1 registers. The N:1 multiplexer will be controlled by M=log₂(N) signals applied to selection control inputs to the scan cell. Accordingly, the size of the LUT will determine the number of observation points that can be monitored using one LUT.

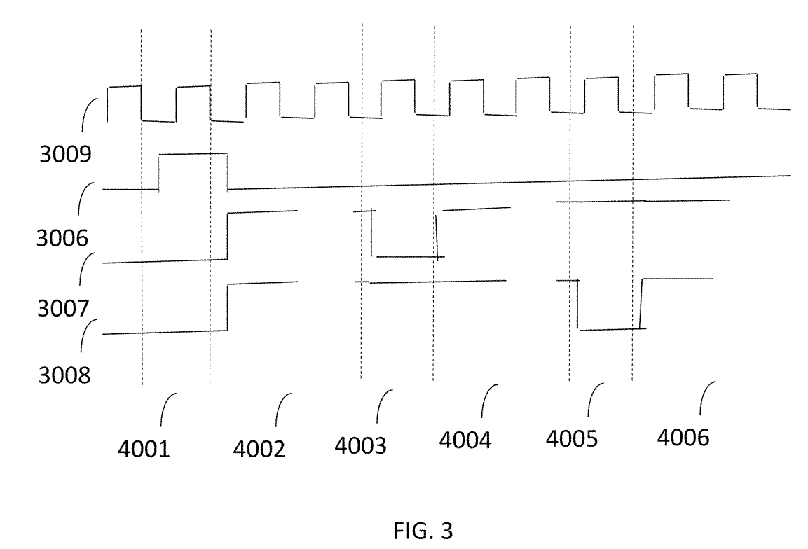

FIG. 3 is a timing diagram demonstrating the way the apparatus functions according to the disclosed method and apparatus. In a first cycle 4001 of signal applied to the scan cell clock input 3009, the load enable control signal 3006 is set to enable registers 3012, 3013. In addition, selection control signals 3007, 3008 are set to propagate the signal at the scan cell data input 3003 to the output of multiplexer 3010. Upon arrival of the a transition of the clock signal, the values of the signals in all three observation points in user logic are captured in registers 3011, 3012, 3013 respectively. After that, in cycles 4002, load enable control signal 3006 is set to disable state changes of registers 3012 and 3013. Simultaneously, and for a number of cycles equal to the number of sequentially connected scan cells 3000, selection control signals 3007, 3008 are set to a value that selects input 3004 of scan cell 3000 to be propagated to the input of register 3011. Upon application of series of transitions of the clock signal, values initially captured in registers 3011 of all scan cells are sequentially transmitted to output 3100. In the next cycle 4003 after that, selection control signals 3007, 3008 are set to propagate the output of register 3012 to the input of register 3011. Upon arrival of transitions of the clock signal, the value stored in register 3012 is copied into register 3011. Then in cycles 4004 for a number of cycles equal to the number of sequentially connected scan cells 3000, selection control signals 3007, 3008 are set to a value that selects input 3004 of scan cell 3000 to be propagated to the input of register 3011. Upon application of series of transitions of the clock signal, values initially captured in registers 3012 of all scan cells are sequentially transmitted to output 3100. In the next cycle 4005 after that, selection control signals 3007, 3008 are set in such a way as to propagate the output of register 3013 to the input of register 3011. Upon arrival of additional transitions of the clock signal, the value stored in register 3013 is copied into register 3011. Then in cycles 4006 for a number of cycles equal to the number of sequentially connected scan cells 3000, selection control signals 3007, 3008 are set to a value that selects input 3004 of scan cell 3000 to be propagated to the input of register 3011. Upon application of series of transitions of the clock signal, values initially captured in registers 3013 of all scan cells are sequentially transmitted to output 3100. Thus all values captured from the observation points in user logic are transmitted into the output 3100 and to external storage.

In some embodiments, load enable signal 3006 and selection control signals 3007, 3008 are distributed to all of the scan cells 3000 of the FPGA device from a single state machine that is implemented in the FPGA. Because distribution of such signals through the FPGA programmable interconnect may encounter a considerable delay, clock cycles in which these signals change their states may need to be extended in time compared to those cycles in which they are stable and only the data value is transmitted between each two neighboring scan cells 3000. The extending the duration of the cycles in which control signals change state will not materially affect the overall performance of data extraction, because there are only 6 such cycles in the whole sequence. For example, assuming that 1000 scan cells 3000 are sequentially connected, a total of 3000 cycles will be required for scanning data out. If 6 of them need to twice as long in duration, this will constitute 0.2% increase in the overall time.

By observing the composition of scan cell 3000 it is clear that only one lookup table is used to service 3 observation points in the user logic. Thus, the overhead in the programmable logic is reduced by three-fold compared to the prior art.

Although the disclosed method and apparatus is described above in terms of various examples of embodiments and implementations, it should be understood that the particular features, aspects and functionality described in one or more of the individual embodiments are not limited in their applicability to the particular embodiment with which they are described. Thus, the breadth and scope of the claimed invention should not be limited by any of the examples provided in describing the above disclosed embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide examples of instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

A group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise. Furthermore, although items, elements or components of the disclosed method and apparatus may be described or claimed in the singular, the plural is contemplated to be within the scope thereof unless limitation to the singular is explicitly stated.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described with the aid of block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

What is claimed is:

1. A scan cell of a field programmable logic array (FPGA) based emulation machine, the scan cell comprising:
a) four scan cell data inputs,
b) a scan cell data output;
c) two scan cell selection control inputs;
d) a scan cell clock input;
e) a first register having a register clock input coupled to the scan cell clock input, a D-input coupled to a first of the three scan cell data inputs and a Q-output;
f) a second register having a register clock input coupled to the scan cell clock input, a D-input coupled to a second of the three scan cell data inputs and a Q-output;
g) a multiplexer having 4 multiplexer data inputs, two multiplexer selection control inputs and a multiplexer data output:
i. the first multiplexer data input coupled to the Q-output of the first register;
ii. the second multiplexer data input coupled to the Q-output of the second register;
iii. the third multiplexer input coupled to the third scan cell data input; and
iv. the fourth multiplexer input coupled to the fourth scan cell data input;
v. the first multiplexer selection control input coupled to a first of the two scan cell selection control inputs;
vi. the second multiplexer selection control input coupled to the second scan cell selection control input; and
h) third register having a register clock input coupled to the scan cell clock input, a D-input coupled to the multiplexer data output and a Q-output coupled to the scan cell data output.

2. The scan cell of claim 1, further comprising a 6-input look up table (LUT) loaded with an LUT-mask to implement a 4:1 multiplexer.

3. A field programmable logic array (FPGA) based emulation machine comprising:
a) a first scan cell as recited in claim 1; and
b) a second scan cell as recited in claim 1, the scan cell data output of the first scan cell coupled to the fourth scan cell data input of the second scan cell.

4. The emulation machine of claim 3, further comprising a scan cell logic controller having two scan cell selection control output and a scan cell clock output, each of the scan cell selection control outputs coupled to a corresponding one of the scan cell selection control inputs of each of the scan cells and the scan cell clock output coupled to the scan cell clock input of each of the scan cells.

5. A field programmable logic array (FPGA) based emulation machine comprising:
a) one look up table (LUT) for each of N observable points in a user logic; and
b) N registers, one of the N registers coupled to the output of the LUT.

6. A can cell of a field programmable logic array (FPGA) based emulation machine, the scan cell comprising:
a) N scan cell data inputs,
b) a scan cell data output;
c) M scan cell selection control inputs, where M=Log₂ (N);
d) a scan cell clock input;
e) a multiplexer having N multiplexer data inputs, M multiplexer selection control inputs and a multiplexer data output:
N−1 registers, each having a register clock input coupled to the scan cell clock input, a D-input, the D-input of N−2 of the registers coupled to a corresponding one of N−2 of the scan cell data inputs in a one to one relationship, N−2 of the multiplexer data inputs are coupled to the Q-output of a corresponding one of the N−2 registers, in a one to one relationship, the N^{th} multiplexer input coupled to the N^{th} scan cell data input, each of the M multiplexer selection control inputs are coupled to a corresponding one of the M scan cell selection control inputs in a one to one relationship, the N−1^{st} register having a D-input coupled to the multiplexer data output and a Q-output coupled to the scan cell data output.
